(19) United States
(12) Patent Application Publication
(10) Pub. No.: US 2017/0098514 A1
(43) Pub. Date: Apr. 6, 2017

(54) HYBRID PEROVSKITE FILMS

(71) Applicant: UT-BATTELLE, LLC, OAK RIDGE, TN (US)

(72) Inventors: David Bruce GEOHEGAN, Knoxville, TN (US); Jong Kahk KEUM, Knoxville, TN (US); Jonathan D. POPLAWSKY, Knoxville, TN (US); Kai XIAO, Knoxville, TN (US); Bin YANG, Oak Ridge, TN (US); Ondrej Edward DYCK, Knoxville, TN (US)

(73) Assignee: UT-BATTELLE, LLC, OAK RIDGE, TN (US)

(21) Appl. No.: 15/286,330

(22) Filed: Oct. 5, 2016

Related U.S. Application Data
(60) Provisional application No. 62/237,168, filed on Oct. 5, 2015.

(51) Int. Cl. H01G 9/20; H01L 51/00

(52) U.S. Cl. CPC H01G 9/2009; H01L 51/0003; H01L 51/0096; H01G 9/2031; H01L 51/0077; H01L 2031/0344

(57) ABSTRACT

Methods for humidity-driven crystallization of hybrid perovskite films as well as the resulting hybrid perovskite films are provided. Hybrid perovskite films can be made by sequentially depositing respective layers of inorganic and organic hybrid perovskite precursors onto a substrate to form a hybrid perovskite film precursor. The hybrid perovskite film precursor can then be exposed to a humidified atmosphere so as to convert the inorganic and organic hybrid perovskite precursors to the hybrid perovskite. The processing desirably results in a void-free hybrid perovskite film. Humidity exposure processing methods can be the enabling step in the formation of large grain size (above 1 micrometer) for building vertical bulk-heterojunction structures through the infiltration of different media in vertical grain-boundaries.

### CROSS REFERENCE TO RELATED APPLICATION

This application claims the benefit of and priority to U.S. Provisional Application No. 62/237,168, filed on 5 Oct. 2015, the entirety of which application is incorporated herein by reference.

### GOVERNMENT RIGHTS

This invention was made with government support under Contract No. DE-AC05-00OR22725 awarded by the U.S. Department of Energy. The government has certain rights in the invention.

### FIELD OF THE INVENTION

The present invention relates generally hybrid perovskites and, more particularly to humidity-driven crystallization of hybrid perovskite films such as may, for example, find use in solar cell and optoelectronic applications.

### BACKGROUND OF THE INVENTION

Hybrid perovskites are a mixture or combination of organic and inorganic ions with the same or similar crystal structure as calcium titanium oxide (CaTiO₃). Halide perovskites are a subset of these materials containing halide ions such as fluoride, chloride or iodide, for example. An example of one such material is the iodide perovskite known as methylammonium lead iodide (CH₃NH₃PbI₃).

Low cost organometal halide perovskite solar cells have emerged as prime candidates to meet the future energy generation demands at the gigawatt-scale, due to the certified-power conversion efficiency (PCE) of around 20% with simple solution-based processing approaches. Formation of such hybrid perovskites typically involves mixing precursors, both organic (e.g., CH₃NH₃I, CH₃NH₃Br, CH₃NH₃Cl, CH(NH₂)₂I, CH(NH₂)₂Br, CH(NH₂)₂Cl) and inorganic (e.g., PbI₂, PbBr₂, PbCl₂), to form the organometal perovskite crystals.

One-step solution-based approaches to the production or growth of hybrid perovskite thin films have typically produced or resulted in the generation of a large density of pinholes or voids within the perovskite films, which can adversely impact photovoltaic performance, especially in planar heterojunction configuration devices. In addition, large variations in film morphology significantly limit device performance reliability, impacting yield.

As a result, two step solution-based processing techniques such as methylammonium iodide (CH₃NH₃I) vapor-assistance and the lead iodide (PbI₂)/CH₃NH₃I bilayer interdiffusion have been developed in an effort directed to the growth of void-free perovskite thin films. These approaches typically employ high temperature (e.g., ≧100° C.) thermal-annealing to drive the diffusion of methylammonium (CH₃NH₃I) molecules into the dense lead iodide (PbI₂) precursor layer to form compact, void-free methylammonium lead triiodide (CH₃NH₃PbI₃) perovskite thin films. Thermal annealing for extended periods, however, has been found and is known to cause the decomposition of such perovskites into PbI₂ which degrades the device performance by acting as defects in the perovskite thin films.

In addition, defects and grain boundaries in perovskite films detrimentally cause significant energy loss and decrease the performance of solar cells. Therefore, suppressing the effect of defects and grain boundaries is important for the pursuit toward the theoretical maximum efficiency with industrially realistic processing techniques.

There is a need and a demand for a simple and reliable solution processing approach for forming, producing, or otherwise making highly-crystalline perovskite films, that are desirably void-free, and which processing desirably does not require thermal annealing, as such processing can find desirable application in or for practical solar cell manufacturing technology, for example.

### SUMMARY OF THE INVENTION

In accordance with one aspect of the subject development, methods for making hybrid perovskite films as well as the hybrid perovskite films themselves are provided.

In particular embodiments, methods for preferably making such a void-free hybrid perovskite film as well as the hybrid perovskite films themselves such as well-suited for low-cost high-performance planar heterojunction photovoltaic devices are provided.

In particular embodiments, methods for making vertical grain-boundary bulk-heterojunction hybrid perovskite films for solar cells and optoelectronic applications as well the hybrid perovskite films themselves are provided.

In accordance with one embodiment, a method for making a hybrid perovskite film involves sequentially depositing, e.g., spin coating, respective layers of inorganic and organic hybrid perovskite precursors onto a substrate to form a hybrid perovskite film precursor and subsequently exposing the hybrid perovskite film precursor to a humidified atmosphere to convert the inorganic and organic hybrid perovskite precursors to the hybrid perovskite. In one embodiment, such exposure can desirably be conducted at or near room temperature. Further, such exposure can desirably result in or produce well-oriented, highly-crystalline perovskite films without thermal annealing processing.

In accordance with one embodiment, methods for making the hybrid perovskite methylammonium lead iodide (CH₃NH₃PbI₃) is provided. One such method involves sequentially spin coating layers of an inorganic hybrid perovskite precursor comprising PbI₂ and layers of an organic hybrid perovskite precursor comprising CH₃NH₃I onto a substrate to form a hybrid perovskite film precursor. The hybrid perovskite film precursor is subsequently exposed to a humidified atmosphere corresponding to ambient air at room temperature with a humidity of at least 25% to convert the inorganic and organic hybrid perovskite precursors to form the hybrid perovskite.

In accordance with another aspect, there is provided a composition of matter comprising a hybrid perovskite film having crystalline columnar grains within a polycrystalline film.

In one embodiment, there is provided a composition of matter comprising a highly-crystalline void-free hybrid perovskite film formed by sequentially spin coating respective layers of inorganic and organic hybrid perovskite precursors onto a substrate to form a hybrid perovskite film precursor. The hybrid perovskite film precursor is exposed to a humidified atmosphere to convert the inorganic and organic hybrid perovskite precursors to the hybrid perovskite.

As used herein references to crystalline columnar grains within a polycrystalline film in general refer to the boundaries between the grains, including GBs and cracks, such as in accordance with aspects of the subject development may be infiltrated with, for example, a hole or electron transport material to create bulk heterojunctions between the columnar grains that enhance the electron and hole separation between grains. The infiltrated hole or electron transport material can act or serve as conduction pathways for holes or electrons to traverse to the p or n-type contact, respectively.

As used herein references to crystalline or, in some embodiments, references to highly crystalline films or materials are to be understood as generally referring to such films or materials that are 100% crystalline within the detection limits of TEM-SAD and X-ray diffraction.

As used herein, references to a vertical grain boundary (Vertical GB) generally refers to a grain boundary that has an origination or termination point at the hole transport layer/perovskite (top of the film shown in FIG. 16a) interface and TiO₂/perovskite interface (bottom of the film shown in FIG. 16a).

As used herein reference to a “void-free” material, such as a perovskite film, are to be understood as generally referring to such a material wherein there are no voids detected within a 100 micron×100 micron SEM image. For example, in accordance with one aspect of the development, a void would have to traverse from the top of the perovskite film to the TiO₂/perovskite interface to be detected. This technique would be able to detect voids with diameters larger than 10 nm, which would be exposed at the surface. Thus, there were be no voids detected within a 50 nm thick (thickness is defined as the direction into the page in image shown in FIG. 7), 2.5 micron wide cross-section of material as shown in FIG. 7. This cross-section includes the perovskite/Spiro and perovskite/TiO₂ interface. TEM was used to image the cross-section and would be able to detect voids that are greater than 5 nm at any point in the film. Cross-sections of the layer stack can also be imaged using SEM techniques with a maximum resolution of 10 nm. An example of a 5 micron long cross-section is shown in the image shown in FIG. 11. Using this technique, in a “void-free” perovskite film no voids would be detect within the detection limit for approximately 100 microns of the cross-section.

Other objects and advantages will be apparent to those skilled in the art from the following detailed description taken in conjunction with the appended claims and drawings.

### BRIEF DESCRIPTION OF THE DRAWINGS

The above-mentioned as well as other features and objects of the invention will be better understood from the following detailed description taken in conjunction with the drawings wherein:

FIG. 1a is an X-ray diffraction pattern of an as-cast glass/PbI₂/CH₃NH₃I film before air-exposure, after air-exposure for 60 minutes, glass/PbI₂ film, and glass/CH₃NH₃I film.

FIG. 1b is an inserted X-ray pole figure acquired from the [110] direction for air-exposure perovskite film.

FIG. 2 is a schematic depiction of the perovskite thin film growth process in accordance with one aspect of the subject development.

FIG. 3 illustrates the evolution of the x-ray diffraction pattern as a function of ambient air-exposure time by monitoring peaks at 12.54° (the (001) plane of PbI₂), and 13.89″ (the (002) plane of CH₃NH₃PbI₃), and 14.05° (the (110) plane of CH₃NH₃PbI₃).

FIG. 4 is a graphical comparison of the PbI₂ (001) plane and the CH₃NH₃PbI₃ (110) plane peak areas as a function of exposure time for the air and water-free environments, respectively.

FIG. 5 illustrates a comparison of the J-V curves of devices without and with TiO₂ acquired under illumination of a one sun simulated condition. The obtained photovoltaic parameters are shown in the inset table.

FIG. 6 illustrates time-resolved photoluminescence at ˜760 nm (circles), showing a biexponential decay characteristic (curve).

FIG. 7 is a bright field cross-sectional TEM image of an entire device with TiO₂ layer. Two typical SAED patterns (Pattern i and Pattern ii) were acquired from CH₃NH₃PbI₃ layer.

FIG. 8 is a detailed view of Pattern i showing identical crystallographic orientation.

FIG. 9 is a detailed view of Pattern ii showing multiple grain orientations within the aperture diameter size of 325 nm.

FIG. 10 is a high resolution TEM image taken from CH₃NH₃PbI₃ layer. The inset of shows the corresponding FFT pattern, viewed along the [110] zone axis. Note that indexing of the (004) and (220) diffraction spots could be switched, because the similar d spacing prevents unambiguous determination of these spot locations.

FIG. 11 illustrates SEM (top) and EBIC (bottom) images of a device with a TiO₂ layer, with the corresponding average line profiles shown in FIG. 12

FIG. 12 illustrates the line profiles taken in the region displayed in FIG. 11.

FIG. 13a illustrates the XRD patterns of original PbI₂ film (top), PbI₂/CH₃NH₃I bilayer film air-exposed for 60 min at room temperature (middle), and thermally annealed perovskite film for 2 h at 100° C. (bottom).

FIG. 13b illustrates the SEM image showing the surface morphologies of 2 h annealed perovskite film.

FIG. 13c illustrates the X-ray pole figure for the (110) plane of the CH₃NH₃PbI₃ crystal corresponding to the image shown in FIG. 13b.

FIG. 14a-c illustrate air-exposure and thermal annealing effect on CH₃NH₃PbI₃ crystalline grain size: with FIG. 14a showing CH₃NH₃PbI₃ film after ambient-air-exposure in ˜30% relative humidity for 1 hour, FIG. 14b showing without air-exposure, the CH₃NH₃I/PbI₂ bilayer films were directly thermal-annealed for 2 hours in a water-free and N₂-filled glovebox; and FIG. 14c showing with air-exposure for 1 hour in an ambient environment (humidity of ˜30%) at room temperature, and followed by thermal-annealing for 2 hours at 100° C. in a water-free, N₂-filled glovebox.

FIG. 15a illustrates the J-V curve of a device under illumination of 100 mW/cm².

FIG. 15b illustrates a Gaussian distribution of the ˜30 device efficiencies.

FIG. 15c illustrates external quantum efficiency (EQE) and integrated short circuit current density (JSC) versus wavelength.

FIG. 15d illustrates reflective absorption and internal quantum efficiency (IQE) versus wavelength. FIG. 15e is an inset illustrating the reflective absorption measurement setup.

FIG. 16a shows the cross-sectional bright field TEM images showing vertical phase morphologies of a device. The inset SAED patterns FIG. 16a (1-6) demonstrate large single crystal grains in perovskite thin film; Patterns 1-3 (white dotted circles), and patterns 4-6 (red dotted circles) were taken along parallel direction, and perpendicular direction to the ITO substrate, respectively.

FIG. 16b illustrates an atomic resolution TEM showing a lattice spacing of 3.17 Å.

FIG. 17a presents a cross-sectional SEM image (up) and a corresponding EBIC image (down) of a device.

FIG. 17b illustrates the corresponding line profiles of the cross-sectional SEM image (upper curve) and EBIC image (lower curve) at the indicated regions as shown inset.

FIG. 17c illustrates a line profile of EBIC current across the GBs between two CH₃NH₃PbI₃ grains. FIG. 17c′ is an insert location whereat the line profile shown in FIG. 17c was taken.

FIG. 17d is a Z-contrast dark-field STEM image (d)

FIGS. 17e-g illustrate corresponding EELS maps, demonstrate a GB infiltrated with Spiro-OMeTAD between two CH₃NH₃PbI₃ grains. The atomic areal density elemental maps (e, iodine; f, carbon; and g, nitrogen) show significant rich content of both carbon and nitrogen and poor iodine in GBs.

FIG. 18a is a cross-sectional TEM image of a device in accordance with one aspect of the subject development.

FIG. 18b presents the corresponding EELS spectra across the GBs between two CH₃NH₃PbI₃ grains, which was taken in the locations as shown in the cross-sectional STEM image FIG. 18c.

FIG. 18d presents the corresponding EELS maps and demonstrate a GB infiltrated with PCBM between two CH₃NH₃PbI₃ grains. The atomic areal density carbon elemental maps shows significant rich content of carbon in GBs.

### DETAILED DESCRIPTION OF THE INVENTION

Selected aspects of the present development concern methods for making hybrid perovskite films as well as such or resulting hybrid perovskite films themselves.

While the subject development will be described further below making specific reference to the hybrid perovskite methylammonium lead iodide (CH₃NH₃PbI₃), the inorganic hybrid perovskite precursor PbI₂ and the organic hybrid perovskite precursor CH₃NH₃I, those skilled in the art and guided by the teachings herein provided will understand and appreciate that the broader practice of the subject development is not so limited. That is, other suitable hybrid perovskites, such as other suitable halide perovskites, including, for example, methylammonium metal trihalide (CH₃NH₃BX₃), formamidinum metal trihalide (H₂NCHNH₂BX₃), methylammonium metal mixed halide (CH₃NH₃BX₃₋ₐYₐ), formamidinum metal mixed halide (H₂NCHNH₂BX₃₋ₐYₐ), where B is lead (Pb), or tin (Sn), both X and Y arc halogen atoms including iodine (I), bromine (Br) or chlorine (Cl), and a can be any number less than or equal to 3, and other corresponding inorganic and organic hybrid perovskite precursors, such as including methylammonium halide, formamidinum halide, metal halide, can be suitably employed.

As described in greater detail below, in accordance with one embodiment, a layer-by-layer sequential depositing method or technique, for example, by spin-coating, is desirably employed to grow “bilayer” CH₃NH₃I/PbI₂ films. As will be appreciated by those skilled in the art and guided by the teachings herein provided, such a layer-by-layer technique can desirably provide or result in a high level or degree of controllability. Subsequently, interdiffusion between PbI₂ and CH₃NH₃I layers can desirably be progressed or driven by a simple humidified air exposure, such as at room temperature, for making well-oriented, highly-crystalline perovskite films without necessitating or requiring thermal annealing processing. More particularly, the resulting high degree of crystallinity desirably can produce or result in a carrier diffusion length of ˜800 nm and a high device efficiency, such as device efficiencies in excess of 10%, in excess of 12%, in excess of 13%, in excess of 14%, or in excess of 15%, e.g., efficiency values which are comparable to values reported for thermally-annealed perovskite films. As will be appreciated, the simplicity and high device performance of such processing approach is or can be highly promising for direct integration into industrial-scale device manufacture.

It has been found that “air exposure”, such as herein described, can have an effect on perovskite crystal size. Further, it has been found that hybrid organometal perovskite materials are very sensitive to humidity, and degrade in humid air. However, the presence of water during film formation appears to solubilize some of the precursors promoting better mixing.

As detailed herein, the effect of humid air exposure during film formation can be utilized to reduce, minimize, avoid or preferably total eliminate the need for or conducting of a thermal annealing step.

Key findings or discoveries of the subject development include:
1. In accordance with one embodiment, a PbI₂ layer and a CH₃NH₃I layer were spin-coated sequentially onto a TiO₂/ITO glass substrate using dimethylformamide (DMF) and 2-propanol, respectively. This initial stage of the as-cast film formed or produced a “trilayer” film with a layer of CH₃NH₃PbI₃ perovskite crystals sandwiched between PbI₂ and CH₃NH₃I precursor layers. The as-cast PbI₂/CH₃NH₃PbI₃/CH₃NH₃I “trilayer” films were then exposed to ambient air at room temperature with a humidity of ˜30%. In-situ, time-resolved X-ray diffraction showed that after 60 minutes, the PbI₂ precursors were found to have completely converted into CH₃NH₃PbI₃ perovskites.
2. The as-cast PbI₂/CH₃NH₃PbI₃/CH₃NH₃I “trilayer” films can convert to single phase CH₃NH₃PbI₃ films even in a water-free environment, although at a much lower rate. Moreover, the presence of ambient water can accelerate the chemical reaction between PbI₂ and CH₃NH₃I.
3. In one embodiment, a prototype device but without an electron transporting layer (ETL), such as titanium oxide (TiO₂) yielded a short circuit current density (J_{SC}) of 18.7 mA/cm², an open circuit voltage (V_{OC}) of 1.02 V, a fill factor (FF) of 72%, and a power conversion efficiency (PCE) of 13.8%. In one embodiment of a typical device with a TiO₂ ETL, improved performance—i.e., a J_{SC} of 19.8 mA/cm², a V_{OC} of 1.03 V, a high FF of 76%, and a PCE of 15.6%, was exhibited. Further, the herein provided and described non-thermal-annealing, room-temperature-air-exposure approach is compatible with roll-to-roll processing, such as to better enable, permit or provide for low-cost flexible photovoltaics.
4. Time-resolved photoluminescence measurements provided or otherwise showed or evidenced a long free carrier lifetime of 114.2 ns. Hall measurements of air-exposed perovskite films showed that the carrier mobility was ˜2.16 cm²/V s, and when combined with carrier lifetime, the carrier diffusion length was estimated to be ˜800 nm, which is comparable to the carrier diffusion length in most thermally-annealed CH₃NH₃PbI₃ perovskite thin films. Therefore, it is believed that the high photovoltaic performance for both types of air-exposed perovskite film devices (with and without TiO₂) can be at least partially attributed to this long carrier diffusion length.
5. A polycrystalline spot pattern, with each domain oriented very similarly over a distance of 325 nm (the aperture diameter), was observed. This suggests that a preferential growth direction, which is consistent with a preferred crystal orientation of [110] orientated parallel to the surface of the substrate as revealed by X-ray pole-figure measurements. A high-resolution TEM image and the corresponding fast Fourier transform (FFT) were taken from the ambient-air-exposed perovskite layer, and clear lattice fringes and a well-ordered crystal lattice were observed. Thus, the high crystallinity and highly-oriented nature of the perovskite layer is believed to contribute significantly to the long carrier diffusion in ambient-air-exposure perovskite thin films.
6. Electron beam induced current (EBIC) measurements indicate that the perovskite layer is the only layer generating free charge carriers that can be collected by the electrodes. A uniform carrier generation was observed in the perovskite film with slight peaks close to the perovskite/TiO₂ and perovskite/Spiro-OMeTAD inherent for a p-i-n structure.
7. A humidity exposure processing treatment mentioned above and followed by post thermal annealing for 1 hour at 100° C. was used to grow perovskite films with large, single-crystal grains (above 2 micrometers) and vertically-oriented GBs (from top to bottom through the entire perovskite layer). The hole-transport medium Spiro-OMeTAD (or any type of hole transport materials whose size is smaller than vertical grain boundaries), or electron transport material such as fullerene derivatives PCBM were then infiltrated into the GBs to form vertically-aligned bulk heterojunctions. Due to the space-charge-regions in the vicinity of GBs, the non-radiative recombination in GBs was significantly suppressed. The GBs became active carrier collection channels. The optimized cells yielded average PCE of 16.3±0.9%, comparable to the best solution-processed perovskite devices, establishing them as important alternatives to growing ideal single crystal thin films in the pursuit toward theoretical maximum PCE with industrially realistic processing techniques.

In view of the above, humidity exposure processing (HEP) methods are contemplated as an important or critical step in the formation in a variety of unique vertical grain boundary perovskite heterojunction (VGBPH) structures that can form through the infiltration of different media, after the formation of the crystals, or during the formation of the crystals.

It is further contemplated that the reduction, minimization, avoidance or total elimination of thermal processing of hybrid perovskite solar cells using HEP methods can or may produce or result in one more, alone or in combination, of the following beneficial features:
1. Layer-by-layer deposition of precursors as can be imagined in roll-to-roll processing could then proceed through different humidity-controlled atmospheres, with or without thermal processing.
2. Control over the crystal size and morphology through controlled HEP methods.
3. Since most films are mixtures of precursors which begin to react immediately and require immediate thermal annealing and/or humidity exposure, the ability to layer precursors and drive the large single-crystal perovskite growth using a simple (subsequent) humidity-exposure treatment gives rise to the possibility of spotting down pixels of different layers and different types of perovskite precursors with dot-matrix deposition or screen printing—for example with different band gaps to make different color absorption or emission, as in an LED display or photodetector array—and then simultaneously driving the formation of the different perovskites by HEP.
4. The additional component necessary to “activate” the grain boundaries to achieve the activated VGBPH structures through the humidity exposure combined with thermal annealing steps, for example, by mixing fullerenes within one of the layers, or by depositing a water-activated infiltration medium, is contemplated.

Further, with humidity exposure being found as a key to the growth of large single-crystals of perovskites which is important to form vertical grain boundaries from top to bottom through the entire active perovskite layer, enabling the VGBPH structures, then single-crystal perovskite films with vertical grain boundaries such as resulted from the HEP methods may result in or constitute compositions of matter wherein:
1. Various morphologies are enabled by the ability to drive crystallization/formation of hybrid perovskite films formed by patterning precursors in a layer-by-layer manner and delaying the processing until a single, fixed-temperature, humidity-controlled processing step. For example, the multi-pixel, multi-composition and band-gap perovskite films.
2. Controllable spacing of crystal size, and therefore density of vertical bulk heterojunctions, allows tuning of the structures for optimal charge generation and charge collection.

Experimental Section

This details a simple room-temperature, air-exposure process that removes, avoids or eliminates the thermal annealing step and drives the interdiffusion of PbI₂ and CH₃NH₃I layers to synthesize highly-crystalline and pinhole-free CH₃NH₃PbI₃ perovskite films. The interdiffusion process and the resulting formation of CH₃NH₃PbI₃ films were characterized by in-situ X-ray diffraction (XRD), which revealed that ambient water molecules are a driving force for the interdiffusion. Perovskite thin film photovoltaic devices resulting from the new air-exposure process displayed a PCE of 15.6%, which is comparable to that of most thermally-annealed perovskite devices.

Device Fabrication and Characterization

A TiO₂ precursor solution was spin-coated onto UV-Ozone treated ITO glass substrates at 2000 rpm for 60 seconds in air. After sintering the TiO₂ precursor film in a furnace at 500° C. for 30 minutes to obtain the anatase phase of TiO₂, a PbI₂ solution (550 mg/mL) and CH₃NH₃I solution (70 mg/mL) were sequentially spin-coated onto the TiO₂ layer at 6000 rpm for 30 seconds in a N₂-filled glovebox. The as-spin-cast “PbI₂/CH₃NH₃I” bilayer films were then maintained in ambient air (humidity of ˜30%) at room temperature to form the perovskite layer. A Spiro-OMeTAD solution (90 mg/mL in chlorobenzene) was doped by adding 10 μL 4-tert-butylpyridine (tBP) and 45 μl lithium bis(trifluoromethane sulfonyl) imide (Li-TFSI, 170 mg/mL in anhydrous acetonitrile). Then, the Spiro-OMeTAD solution was spin coated at 2000 rpm for 40 seconds, and then left in a desiccator overnight. Finally, silver was thermally-evaporated at deposition rate of 1 Å/s at a vacuum level of 10⁻⁶ mbar to form a 100 nm-thick film. For the thermally annealed device fabrication, the as-grown bilayer films were then placed in ambient air (humidity of ˜30%) for 60 minutes until the color of the films was dark brown. Subsequently, the films were thermally annealed at 100° C. for 2 hours covered by a glass petri dish in an N₂-filled glovebox.

Current density-voltage (J-V) curves were measured using a Keithley 2400 source meter in a N₂-filled glovebox. The devices were illuminated at 100 mW/cm² (AM 1.5 G solar spectrum) from a solar simulator (Radiant Source Technology, 300 W, Class A). Prior to each measurement, the light intensity was carefully calibrated using a NIST-certified Si-reference cell. The J-V curves were obtained by scanning from reverse bias to forward bias, and forward bias to reverse bias, with a 50 ms sweep delay time. The active area was ˜6.5 mm², which was measured and calculated by optical microscopy. For incident photon-to-current efficiency (IPCE) measurements, the light source was chopped at 35 Hz and the output electrical signal was collected by a lock-in amplifier (Merlin Radiometric Lock-In Amplifier, Newport) under short-circuit conditions: A calibrated silicon diode (70356-70316NS, Newport) with a known spectral response was used as a reference.

Film Characterization

An X-ray difflactometer (Panalytical X'Pert MPD Pro) with Cu-Kα radiation (λ=1.54050 Å) was used to measure the x-ray diffraction (XRD) patterns (0/20 scans). The step size and scan rate was 0.0167113° and 0.107815°/s, respectively. The X-ray pole figure was acquired using an X-ray diffractometer (Panalytical X'Pert MRD Pro) with Cu-Kα radiation (λ1.54050 Å). A two-theta-angle of 14.05° was employed to find the orientation of the (110) plane of the CH₃NH₃PbI₃ perovskites.

Surface morphological images were measured with a scanning electron microscope (SEM, Zeiss Merlin) with an accelerating voltage of 5 kV. A Zeiss Libra 200MC was used to perform the transmission electron microscope (TEM) measurements with an operating voltage of 200 kV. Cross-sectional TEM specimens (thickness of ˜50 nm) were prepared by focused ion beam (FIB) milling with a final polish. An accelerating voltage of 10 kV and beam current of 20 pA were used to minimize beam induced surface damage. For the selected area diffraction pattern measurements, an aperture diameter of 325 nm, which exceeds the thickness of our perovskite layer in the device, was used.

Electron beam induced current mapping (EBIC) and associated scanning electron microscopy (SEM) measurements were conducted in a Hitachi 4800-CFEG, which was equipped with a Gatan EBIC system. A Stanford Research Systems model SR570 low-noise current preamplifier was applied to amplify the EBIC currents. In order to ensure a good signal-to-noise ratio and minimal electron beam induced damage, an accelerating voltage of 1.5 kV with beam currents of 30-50 pA was used. 5 kV Argon ion milling with a Gatan Illion+ was employed at liquid nitrogen temperatures to create a smooth cross-sectional surface to reduce artifacts due to topography. It should be emphasized that these samples can be damaged during argon ion milling and electron beam exposure, which can reduce the EBIC signal intensity, and only the first EBIC scan are displayed.

Photoluminescence (PL) spectra were measured using a spectrometer (Acton SP2300) equipped with a CCD (Princeton Instruments, Pixis 256), which was coupled to a microscope. The time-resolved PL was measured by using a time correlated single photon counting (TCSPC) (Horiba Scientific with Picosecond Photon Detection Module, PPD-850 and Fluorohub model: Horiba JY IBH). The PPD-850 was mounted to a second port of the same spectrometer. The perovskite films were excited using a second harmonic (400 nm) of a Ti:sapphire laser (Coherent, Mira 900) (800 nm, 5 ps pulses, 76 MHz repetition rate). To match TCSPC requirements, the laser repetition rate was reduced to ˜5 kHz using a pulse picker (Coherent). The output from the pulse picker was frequency doubled using an ultrafast harmonic generator (Coherent 5-050) and directed into a microscope to illuminate the perovskite films through a 10× microscope objective (beam spot size ˜21×39 μm) with an average power of ˜0.7 mW. In order to stabilize the specimens under illumination, they were exposed to a 400 nm laser light for ˜20-30 minutes. The quartz side of the samples was irradiated. The absorbance measurements were conducted with a Varian Cary 5000 spectrophotometer.

A HMS-3000 Hall Measurement System was employed to conduct the characterization of the carrier mobility of the air-exposed perovskite films, which were prepared on silicon substrate with dimension of 1 cm×1 cm and thickness of 350 nm. When combined with carrier lifetime measured previously, the carrier diffusion length was estimated according to equation

$$L = \sqrt{\frac{kT}{q} μ τ} ,$$

where, k is the Boltzmann constant, T is temperature, q is elementary charge, μ is carrier mobility, and τ is the carrier lifetime.

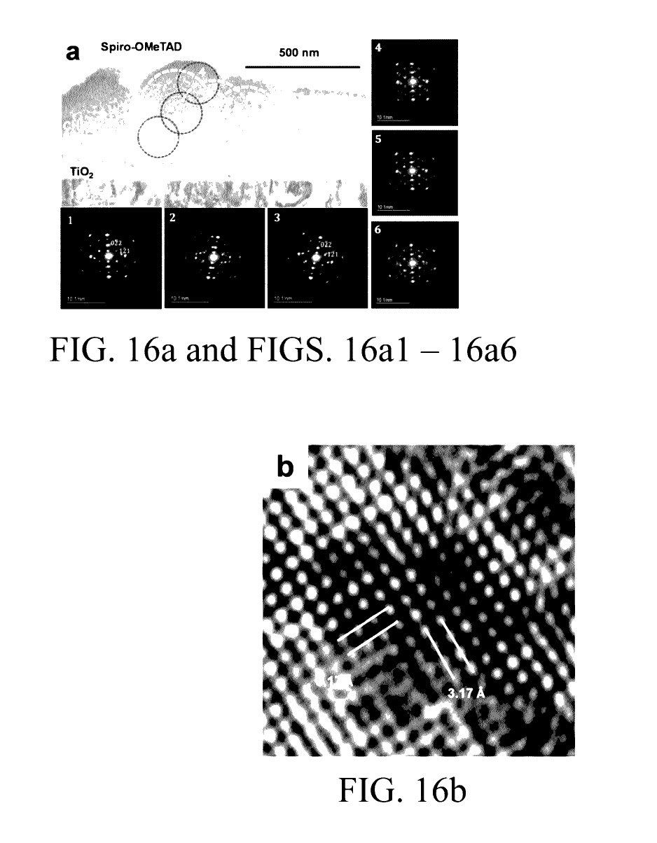

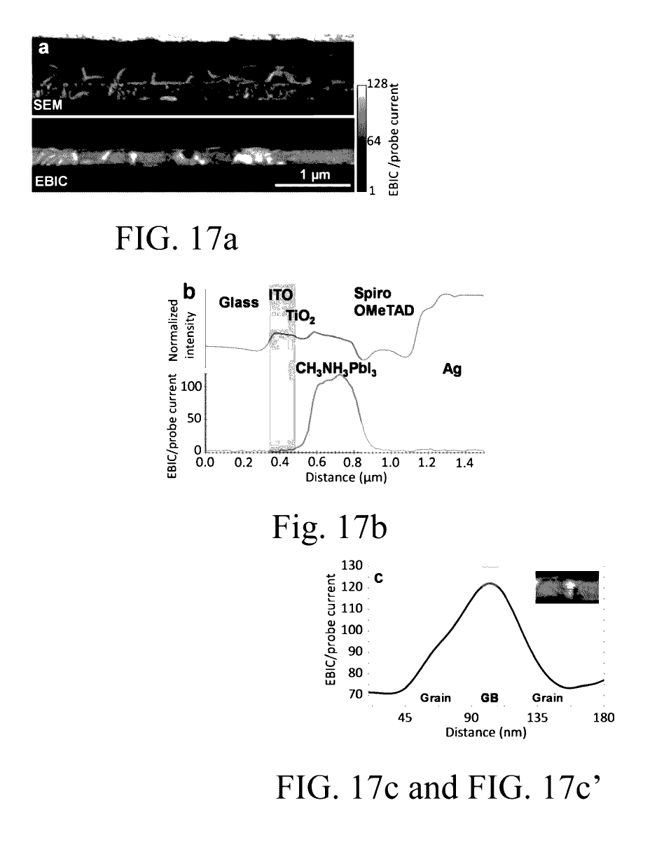

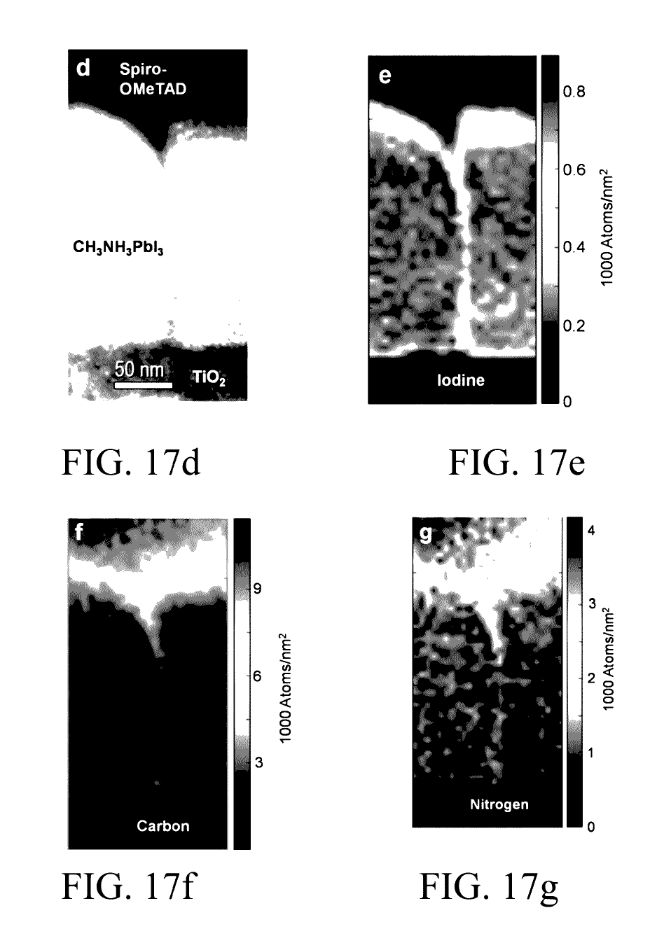

The surface morphological images were taken with a scanning electron microscope (SEM; Zeiss Merlin SEM). The SEM images were acquired by the Inlens model, line average scanning with a gun voltage of 5 kV. The transmission electron microscope (TEM) used in these studies was a Zeiss Libra 200MC operated at 200 kV. The electron energy loss spectroscopy (EELS) images were acquired with a beam current of 158 pA, as measured on the calibrated spectrometer CCD in vacuum, with an exposure time of 0.1 seconds per pixel and a pixel size of 5.3×5.3 nm². Spectra were background subtracted and fit with a hydrogenic model scattering cross-section. With a known beam current and calibrated spectrometer, the fitting parameter could be interpreted as atomic areal density, and a quantitative value is obtained within ˜10%. Selected area diffraction was taken with an illuminated area of 325 nm for Pattern 1-3 and an illuminated area of 180 um for Pattern 4-6 as shown in FIG. 16a. In order to reduce the beam intensity such that a beam stop was not needed, the monochromator slit was moved to the tail of the beam profile to decrease the beam current (˜15 pA) and an exposure time of 0.1 seconds was used. All imaging was acquired under parallel illumination in TEM mode, with the exception of FIG. 17d which is a high angle annular dark field (HAADF) image taken in STEM mode. The tested ultra-thin cross-sectional specimens (˜50 nm) were prepared by focused ion beam (FIB) milling with a final polish at an accelerating voltage of 10 kV and beam current of 20 pA to minimize beam induced surface damage.

Discussion

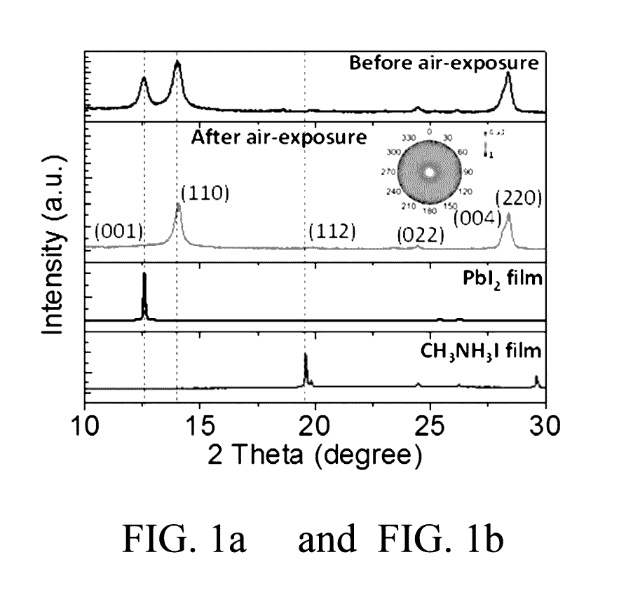

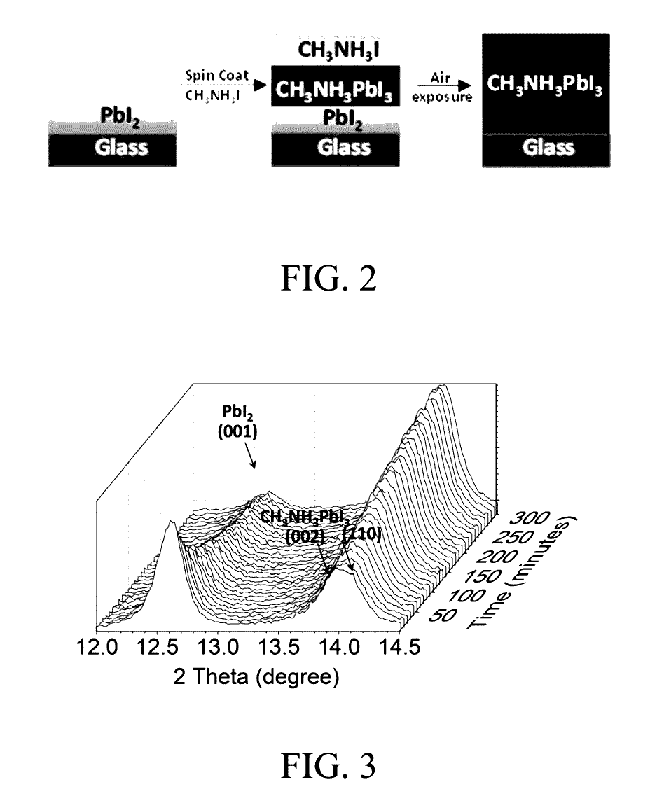

The PbI₂ layer and CH₃NH₃I layer were spin-coated sequentially onto TiO₂/ITO glass substrates using dimethylformamide (DMF) and 2-propanol, respectively. As shown in FIG. 1, the initial as-cast “bilayer” thin film not only exhibited Bragg peaks associated with PbI₂ crystal (001) planes at 12.54°, but also strong CH₃NH₃PbI₃ peaks at 14.05° and at 28.37° for the (110) plane and (220) planes, respectively, indicating the formation of perovskite crystals resulting from the CH₃NH₃I spin-coating process. It should be noted that another peak appeared at 13.89°, which was indexed as the perovskite CH₃NH₃PbI₃ (002) plane using Rietveld analysis. Therefore, this initial stage of the as-cast film can be viewed as a “trilayer” film with a layer of CH₃NH₃PbI₃ perovskite crystals sandwiched between PbI₂ and CH₃NH₃I precursor layers (FIG. 2). The as-cast PbI₂/CH₃NH₃PbI₃/CH₃NH₃I “trilayer” films were exposed to ambient air at room temperature with a humidity of ˜30%. After 60 minutes, the PbI₂ precursors were found to have completely converted into CH₃NH₃PbI₃ perovskites, as indicated by the disappearance of the PbI₂ (001) Bragg peak (FIG. 1). X-ray pole figures were used to probe the global orientation and crystallographic texture of such films, and FIG. 1 indicates they were well-oriented with the CH₃NH₃PbI₃ (110) planes orientated parallel to the surface of the substrate. Note that this plane has been theoretically identified as the most stable surface in the tetragonal phase of CH₃NH₃PbI₃. The SEM image shows that the CH₃NH₃PbI₃ perovskite film is free of pinholes, although a few large (˜1 μm) “flower-like” perovskite crystals are observed. Atomic force microscopy was used to understand the surface roughness of the film and the large “flower-like” crystals. The root-mean-square roughness of a 20 μm×20 μm area on an air-exposed film was ˜34 nm, and large “flower-like” crystals having an average height of ˜70 nm were observed, indicating they protruded above the surface of the film.

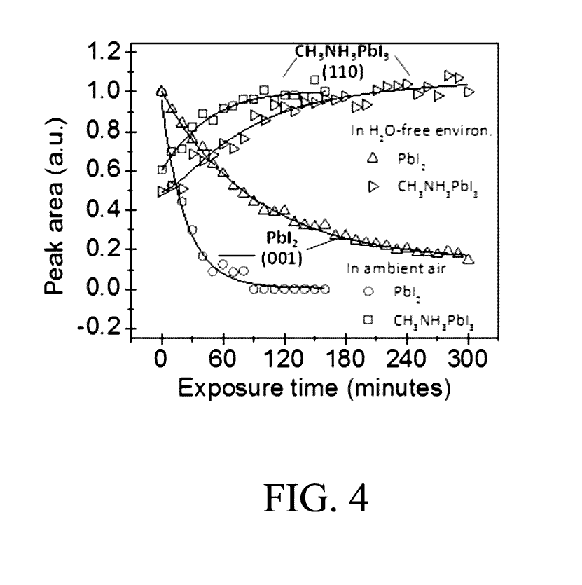

To investigate the evolution of the perovskite phase in the as-cast thin films during ambient exposure, in-situ X-ray diffraction was employed to monitor the PbI₂ (001) and CH₃NH₃PbI₃ (110) Bragg peaks as a function of time. As shown in FIG. 3, with increasing exposure time the PbI₂ Bragg peak gradually decreased while the CH₃NH₃PbI₃ Bragg peak simultaneous increased (see FIGS. 3 and 4), indicating the PbI₂ and CH₃NH₃I precursors were reacting to grow the CH₃NH₃PbI₃ crystals. After 60 minutes of exposure, the PbI₂ peak completely disappeared, and the intensity of the CH₃NH₃PbI₃ (110) peak correspondingly stabilized, indicating that the reaction and crystallization were complete. To understand whether humidity was the driving force for the interdiffusion, air exposure studies were conducted on a similar initial PbI₂/CH₃NH₃PbI₃/CH₃NH₃I “trilayer” film at room temperature in a water-free chamber (H₂O<0.1 ppm). Interestingly, despite an essentially dry environment, the peak area intensity of the PbI₂ (001) plane was again found to decrease and the peak intensity of the CH₃NH₃PbI₃ (110) plane correspondingly increased, however more slowly. This suggests that PbI₂ and CH₃NH₃I can gradually convert to CH₃NH₃PbI₃ even in a water-free environment, although at a much lower rate as shown in FIG. 4. It is thus hypothesized that ambient water accelerates the chemical reaction between PbI₂ and CH₃NH₃I due to the existence of a more reactive and metastable CH₃NH₃PbI₃.H₂O phase, which then spontaneously releases its water molecules at room temperature.

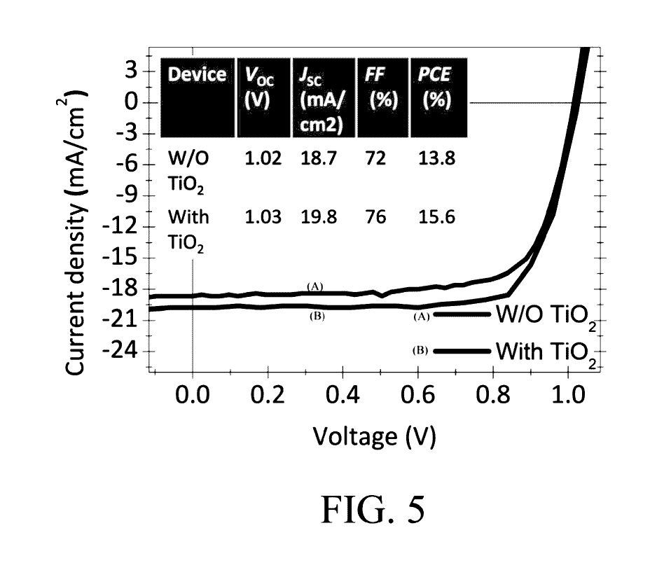

To assess the applicability of the films for solar cells, prototype devices were fabricated. The photovoltaic performance of electron transporting layer (ETL)-free devices (ITO/CH₃NH₃PbI₃/Spiro-OMeTAD/Ag) based on our air-exposed perovskite films were first examined. In order to grow compact perovskite layers, a UV-ozone treatment for 10 minutes was used to generate a hydrophilic ITO glass surface, as shown by water contact angle measurements. Surprisingly, when swept from forward bias to reverse bias, the device without TiO₂ yielded a J_{SC} of 18.7 mA/cm², a V_{OC} of 1.02 V, a FF of 72%, and a PCE of 13.8% (FIG. 5). The cross-sectional SEM image acquired from such high performance TiO₂-free device showed a compact perovskite layer. In order to verify the J_{SC} from the J-V curve, the external quantum efficiencies (EQEs) were measured. By integrating the EQE curve across the standard AM 1.5 G solar spectrum (100 mA/cm²), a J_{SC} of 18.2 mA/cm² was calculated, which is consistent with the J_{SC} measured from the J-V scan. For comparison, a TiO₂ ETL was incorporated into the devices, and as shown in FIG. 5, the typical device exhibited improved performance—i.e., a J_{SC} of 19.8 mA/c², a V_{OC} of 1.03 V, a high FF of 76%, and a PCE of 15.6% when swept from forward bias to reverse bias.

It should be noted that both types of devices, with and without TiO₂, exhibited hysteresis characteristics. To reveal how the J-V hysteresis affects the maximum power output from the devices, a device was measured in both forward and reverse scan mode, which showed a PCE of 15.2% and 8%, respectively. The photocurrent as a function of time measured at the maximum power output point (0.792 V) under an illumination of 100 mW/cm² was then acquired. The photocurrent density saturated at ˜16 mA/cm², and the device showed a stable PCE of 12.7% despite of the strong J-V hysteresis.

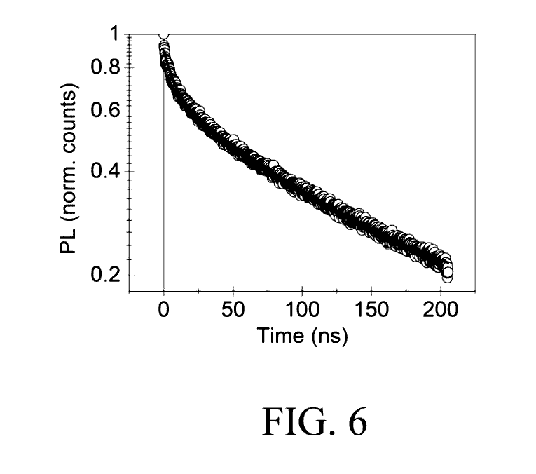

To further understand the origin of their high photovoltaic performance, the time-resolved photoluminescence (PL) at ˜760 nm (FIG. 6) was first characterized. Based on the biexponential fitting results, two lifetimes are obtained: a short lifetime of 8.3 ns and a long lifetime of 114.2 ns. The fast decay was ascribed to significant surface recombination, while the slow decay was attributed to the dominant free carrier decay within the bulk film. Hall measurements of the air-exposed perovskite films showed that the carrier mobility was ˜2.16 cm²/V s, and when combined with carrier lifetime measured previously, the carrier diffusion length was estimated to be ˜800 nm, which is comparable to the carrier diffusion length in most thermally-annealed CH₃NH₃PbI₃ perovskite thin films. Therefore, the high photovoltaic performance for both types of air-exposed perovskite film devices (with and without TiO₂) can be partially attributed to this long carrier diffusion length.

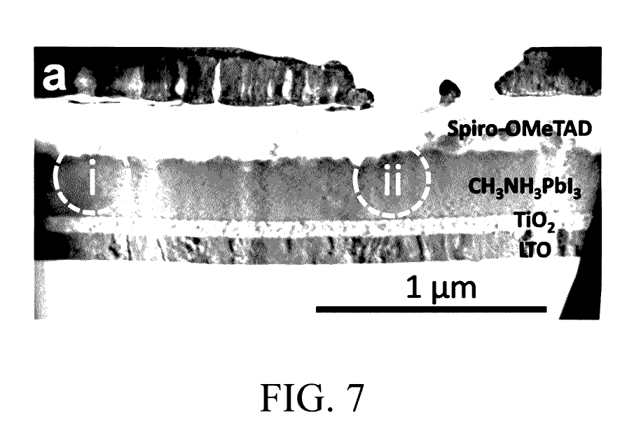

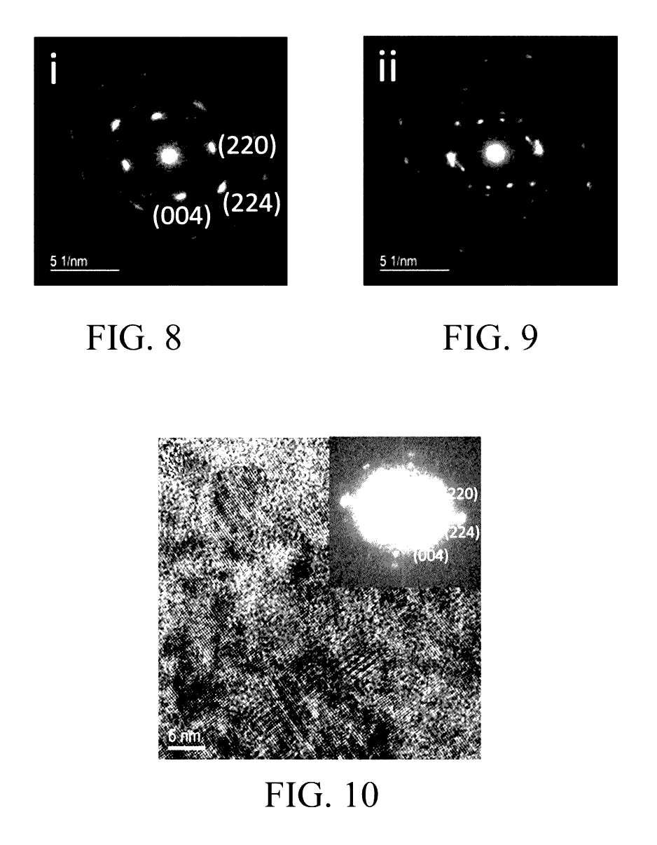

To understand the cross-sectional morphology and crystallinity of the devices, cross-sectional TEM images and SAED studies were performed. In FIG. 7, the compact CH₃NH₃PbI₃perovskite layer was clearly identified in the cross-sectional TEM image of the subject high performance device, which has an ITO/TiO₂/CH₃NH₃PbI₃/Spiro-OMeTAD/Ag architecture. A series of SAED patterns were acquired along the direction parallel to the glass substrate to examine the crystallographic features of the perovskite film. Two typical SAED patterns are shown in FIG. 7. A polycrystalline spot pattern (Pattern I, also shown in FIG. 8) was observed with each domain oriented very similarly over a distance of 325 nm (the aperture diameter), suggesting a preferential growth direction, which is consistent with a preferred crystal orientation of [110] as revealed by X-ray pole-figure measurements. Pattern i is consistent with observations in the literature where CH₃NH₃PbI₃ is viewed along the [110] zone axis. However, it should be noted that regions where the crystals did not orient similarly, as shown by Pattern ii (also shown in FIG. 9), were also observed. A high-resolution TEM image (FIG. 10) and the corresponding fast Fourier transform (EFT) (inset of FIG. 10) were taken from the ambient-air-exposed perovskite layer, and clear lattice fringes and a well-ordered crystal lattice were observed, despite the presence of surface damage due to focused ion beam milling during sample preparation. Thus, it is concluded that the high crystallinity and highly-oriented nature of the perovskite layer contributes significantly to the long carrier diffusion in ambient-air-exposure perovskite thin films.

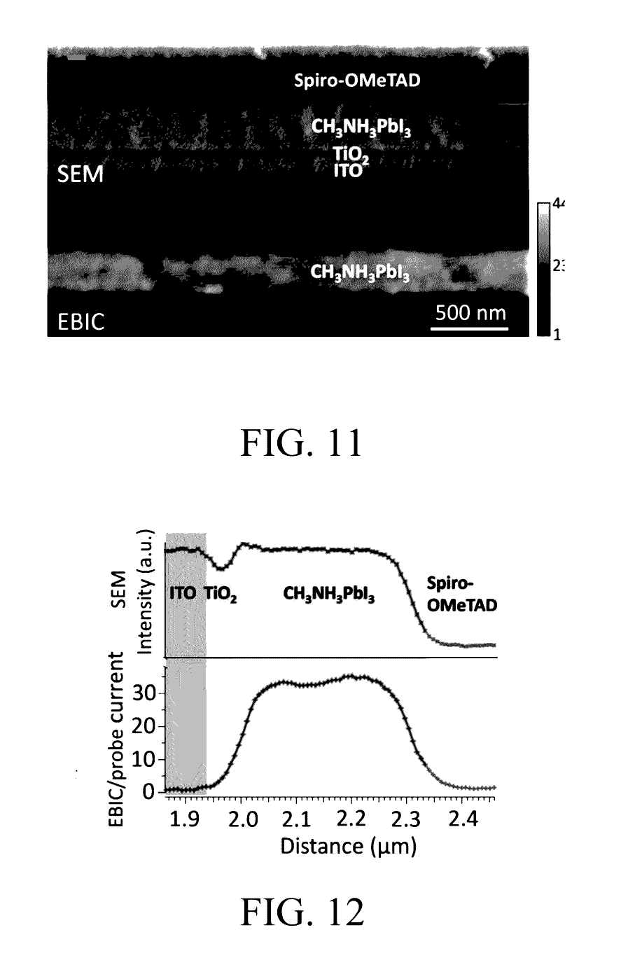

Electron beam induced current (EBIC) measurements were further employed to investigate the device operation mechanism. The cross sectional SEM and corresponding EBIC images are shown in FIG. 11. The line profiles of the SEM and corresponding EBIC were taken across the entire device, as indicated in FIG. 12. The ERIC signal was only observed within the CH₃NH₃PbI₃ perovskite layer, indicating that the perovskite layer was the only layer generating free charge carriers that can be collected by the electrodes. A uniform carrier generation was observed in the perovskite film with slight peaks close to the perovskite/TiO₂ and perovskite/Spiro-OMeTAD inherent for a p-i-n structure.

In summary, a simple room temperature air-exposure approach was developed to grow high crystalline, well-orientated perovskite films, resulting in a long carrier diffusion length of ˜800 nm. The devices with and without TiO₂ ETL yielded PCE of 15.6% and 13.8%, respectively, which are comparable to that of most thermally-annealed perovskite devices. The non-thermal-annealing, room-temperature-air-exposure approach is compatible with roll-to-roll processing, which enables very low-cost flexible photovoltaics.

In one aspect of the subject development, perovskite thin films with large single crystalline grains and vertically oriented grain boundaries were grown through a simple solution-based layer-by-layer spin-coating method followed by air exposure and thermal annealing treatments. The grain boundaries (GBs) were shown to be infiltrated with p-type doped 2,2′,7,7′-tetrakis[N,N-di(p-methoxyphenylamine)]-9,9-spirobifluorene (Spiro-OMeTAD) to form a new type of vertical bulk heterojunction (BHJ) structure within the perovskite films as demonstrated by electron energy loss spectroscopy (EELS) study and electron beam induced current (EBIC) mapping. These measurements also showed that the BHJs at GBs can significantly reduce non-radiative recombination losses as well as enhance carrier collection in the devices. This approach leads to high performance devices with near 100% internal quantum efficiencies (IQEs) in the visible light range and high average PCE of 16.3±0.9%.

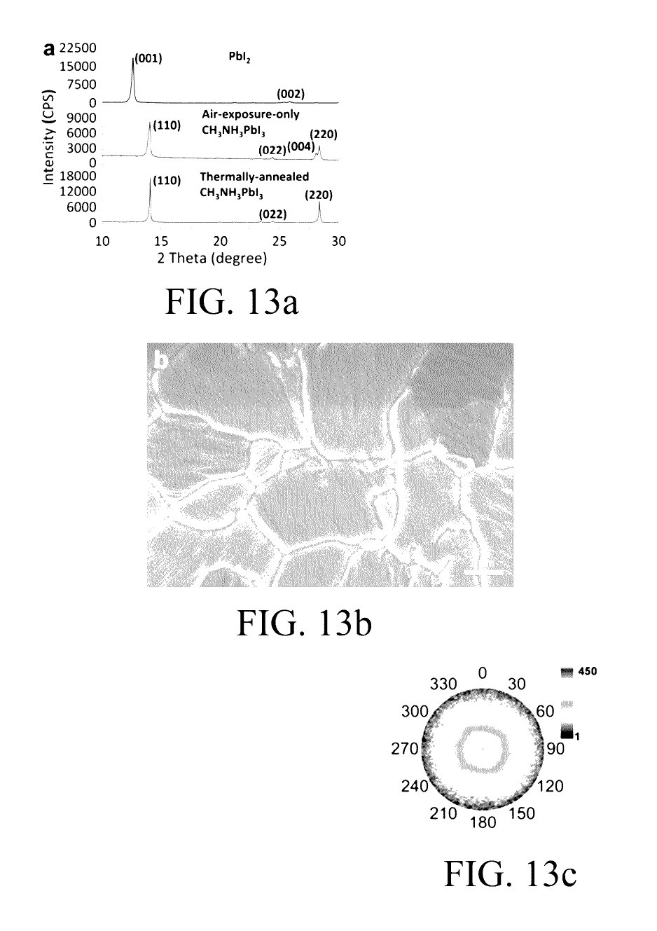

A sequential spin-coating method was applied to fabricate the PbI₂/CH₃NH₃I bilayer films in a N₂ filled glovebox. The as-casted bilayer films were initially exposed in ambient air (humidity of ˜30%) during the chemical formation of the perovskite layers. X-ray diffraction (XRD) was employed to examine the chemical reaction between the two precursor layers (PbI₂/CH₃NH₃I) during room-temperature air exposure. The spin-coated PbI₂/CH₃NH₃I bilayer film was found to have completely converted into a polycrystalline perovskite film after air exposure for 60 min, as shown by the disappearance of the PbI, Bragg peaks (in the top most XRD pattern shown in FIG. 13a) and the appearance of the CH₃NH₃PbI₃ Bragg peaks (center XRD pattern shown in FIG. 13a). It is clear from the data that the chemical reaction of PbI₂/CH₃NH₃I and crystallization of perovskites can occur even without thermal annealing to drive interdiffusion between PbI₂ and CH₃NH₃I, which may be due to formation of a more reactive intermediate phase CH₃NH₃PbI₃.H₂O during air exposure at room temperature. A subsequent treatment of 100° C. thermal annealing resulted in a 2-fold increase in the (110) peak intensity and narrowed down the (110) peak width (lower most XRD pattern shown in FIG. 13a), which indicates significantly enhanced crystallinity in air-exposure-only perovskite films. Scanning electron microscopy (SEM) imaging showed that grains larger than 2 μm in the lateral direction were observed after annealing for 2 h (FIG. 13b). The X-ray pole figure measurement was used to probe the global orientation and crystallographic texture of the perovskite crystals, which clearly indicated that the grains in the 2 h annealed perovskite films showed excellent orientation, as suggested by a maxima orientation of [110] (FIG. 13c).

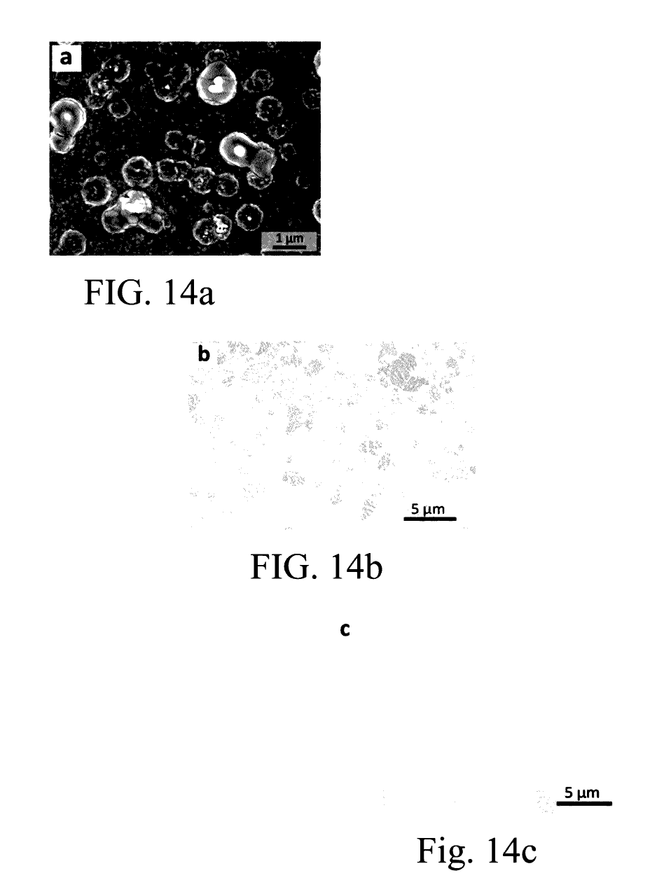

The as-cast PbI₂/CH₃NH₃PbI₃/CH₃NH₃I “trilayer” films can convert to single phase CH₃NH₃PbI₃ films even in a water-free environment (FIG. 14a). Ambient humid air exposure is one significant factor to grow large single crystalline grains, which are larger than the grains in the non-air exposed perovskite films (FIG. 14b). The humidity exposure processing methods may be the enabling step in the formation in large grain size (above 2 micrometer) (FIG. 14c) that could be used to build vertical bulk-heterojunction structures through the infiltration of different media in vertical grain-boundaries.

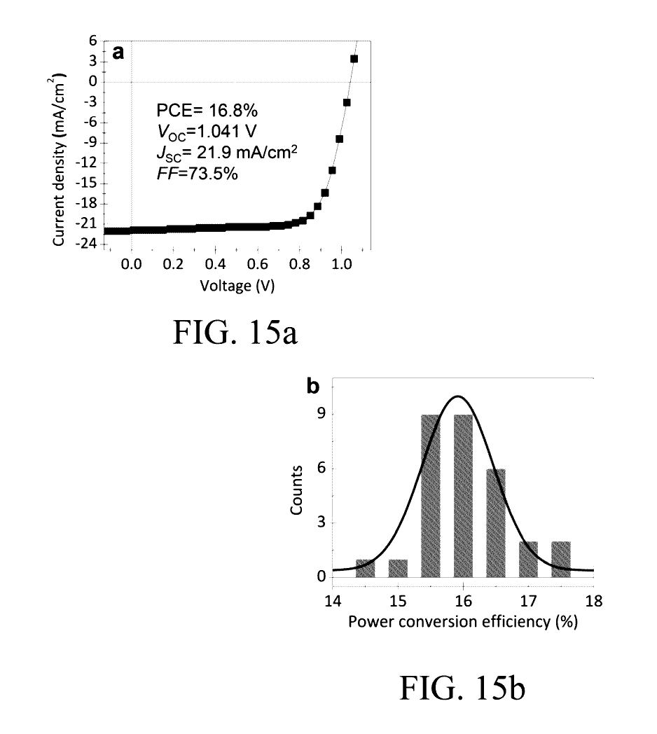

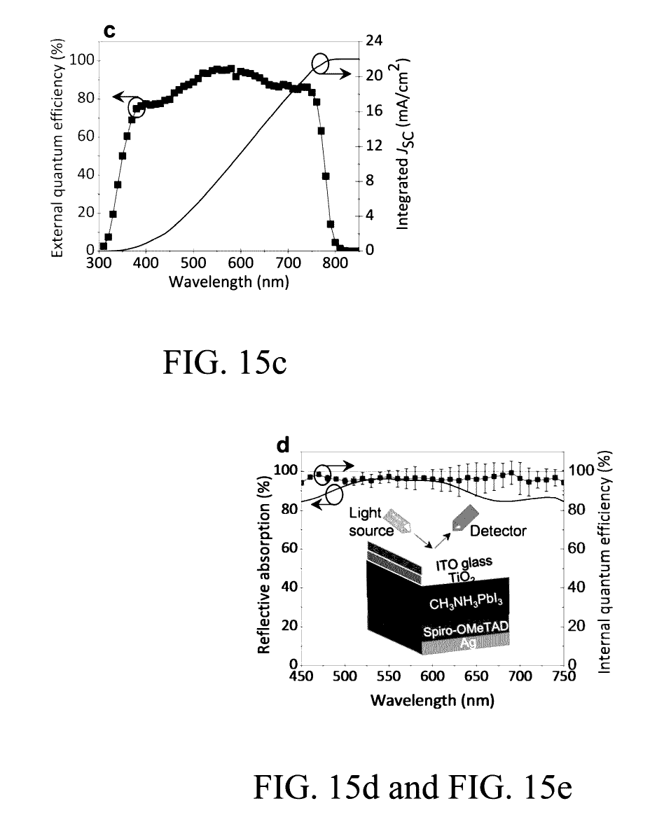

The large perovskite grain films, as shown in. FIG. 14c, were applied to make solar cells. The typical device yielded a short-circuit current density (J_{SC}) of 21.9 mA/cm², an open-circuit voltage (V_{OC}) of 1.041 V, a fill factor (FF) of 73.5%, and a PCE of 16.8%, when measured by sweeping from forward bias (1.2 V) to reverse bias (−0.2 V). (See FIG. 15a.) Negligible J-V hysteresis was observed from this device when scanning from forward bias (1.2 V) to reverse bias (−0.2 V) and from reverse bias (−0.2 V) to forward bias (1.2 V), with a 50 ms sweep delay time. A Gaussian distribution of device efficiencies based on ˜30 devices is shown in FIG. 15b, with a mean PCE of 16.3±0.9%.

External quantum efficiencies (EQEs) of these devices were also measured. A typical EQE curve is shown in FIG. 15c. The EQE spectrum integration over the AM 1.5 G solar spectrum (100 mW/cm²), yields a J_{SC} of 22 mA/cm² (FIG. 15c), which is consistent with the J_{SC} obtained from J-V sweep. To further examine the internal quantum efficiency (IQE), the absorption spectrum was measured in reflectance, mimicking the light absorption process in real devices, as depicted in the inset of FIG. 15d. It is remarkable that the IQE, calculated dividing the EQE by the reflective absorption, approaches 100% from 450 nm to 750 nm (FIG. 15d).

IQE near 100% evidences remarkable carrier generation and collection efficiencies in the subject devices. In order to reveal the origin of the exceptional cell performance, the vertical microstructure of the perovskite film in the devices was investigated. Transmission electron microscopy (TEM) was applied to image the cross-sectional morphology of the entire device with architecture (ITO/TiO₂/CH₃NH₃PbI₃/Spiro-OMeTAD/Ag). Large oriented-crystalline grains and vertically-aligned GBs were clearly identified (FIG. 16a). Similar crystallographic orientations along the direction parallel to the substrate were observed, as shown by two typical selected area electron diffraction (SAED) patterns acquired in two separate grains (patterns 1 and pattern 3); Pattern 2 is a superposition of patterns 1 and 3 as the SAED was taken across the GB (FIG. 16a). The lateral size of typical single crystal domains exceeded our aperture size of 325 nm, which makes electrons easily illuminating single crystal regions. To investigate the vertical single crystal grain size, a smaller SAED aperture with 180 nm diameter was inserted and used to acquire a series of very similar SAED patterns (pattern 4, 5, 6) perpendicular to the film substrate through the entire ˜450 nm-thick perovskite layer. The results suggest that a single crystal domain crosses the entire film in perpendicular direction. An atomic resolution TEM image (FIG. 16b) showed clear lattice fringes indicating the formation of a crystalline structure with a lattice spacing of 3.17 Å, which could be indexed as (220) of the tetragonal CH₃NH₃PbI₃ phase. High resolution TEM/SAED studies clearly showed a high degree of crystallinity and a low density of GBs in the subject perovskite films, which could be one reason for excellent carrier generation and collection efficiencies.

EBIC measurements were further applied to reveal local electrical properties in single crystal grains as well as vertical GBs within the active layer. In EBIC, highly-energetic electrons were used to generate several electron-hole pairs in targeted areas of a semiconductor, which were separated due to internal electric fields and collected at electrodes. By scanning the electron beam, EBIC measurements revealed several important electrical characteristics, such as presence of internal electric fields, the location of p-n junctions at the mesoscopic scale, recombination centers (e.g., grain boundaries), and estimation of minority carrier diffusion lengths. FIG. 17a shows a cross-sectional SEM image and corresponding EBIC image of a device. The line profiles of the cross-sectional SEM image and EBIC image are presented in FIG. 17b. It is clear from these data that electrical current is generated throughout the entire perovskite active layer, which is indicative of p-i-n structure. Moreover, the EBIC signal in the GB region was stronger compared to the grain regions (FIG. 17a). A line profile of EBIC current across a typical GB between two CH₃NH₃PbI₃ grains showed that about 70% higher EBIC current was measured in the vicinity of the GB with respect to the surrounding grains (FIG. 17c), which implies that the GBs are active channels for carrier separation and collection rather than strong recombination regions.

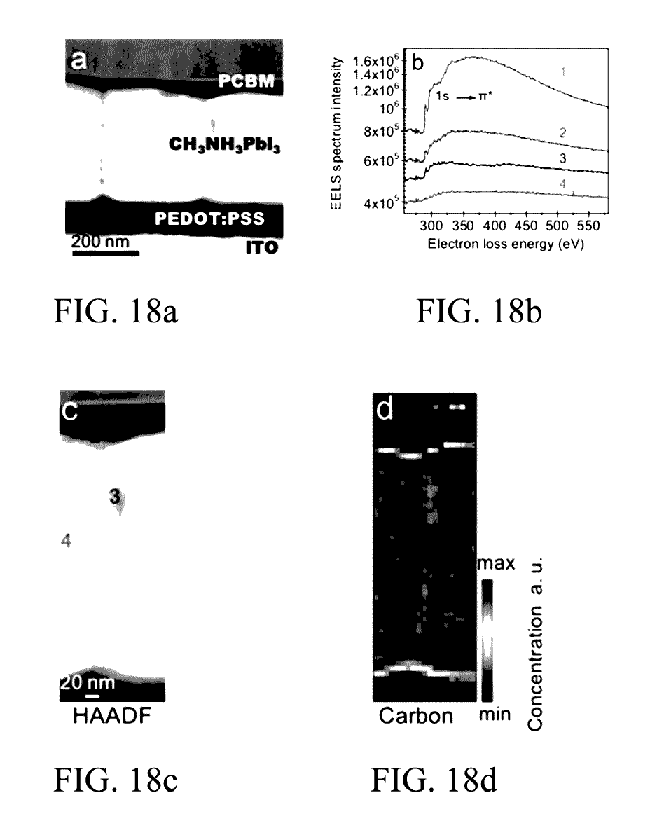

In order to understand the underlying causes of superior carrier collections in GBs, the presence of materials in the GBs had to be unveiled. Thus, the GBs between these vertically-aligned single-crystalline grains were examined with Z-contrast scanning transmission electron microscopy (Z-STEM) and EELS mapping. FIG. 17d shows the cross-sectional morphology of two CH₃NH₃PbI₃ grains and a vertical GB. Since iodine is only present in CH₃NH₃PbI₃, CH₃NH₃I, and PbI₂, and both carbon and nitrogen are rich in organic material Spiro-OMeTAD, EELS mapping images of iodine (FIG. 17e), carbon (FIG. 17f), and nitrogen (FIG. 17g) atomic areal densities were acquired. The evidence of poor iodine and rich carbon and rich nitrogen in GBs compared to the surrounding grains indicates that the Spiro-OMeTAD was most likely infiltrated in the boundaries. As shown in FIG. 18a-d, methanofullerene Phenyl-C61-Butyric-Acid-Methyl-Ester (PCBM) could also be infiltrated in the grain boundaries. The charge transport materials that are used to form VGBPH structures are not limited to Spiro-OMeTAD and PCBM. They can be any n-type electron transports such as fullerene or fullerene derivatives, zinc oxide (ZnO) and p-type hole transporters such as poly(3,4-ethylenedioxythiophene) polystyrene sulfonate (PEDOT:PSS), Poly[bis(4-phenyl)(2,5,6-trimentlyphenyl)amine (PTAA), nickel oxide (NiOx) and molybdenum trioxide (MoOx). Moreover, the infiltration of Spiro-OMeTAD in GBs would form BHJs between perovskite grains and GBs within the active layer. The enhancement in carrier collection could be ascribed to BHJs between perovskite grains and p-type doped Spiro-OMeTAD filled GBs. The space charge regions between the CH₃NH₃PbI₃ grains separate photogenerated electron-hole pairs and suppress the carrier recombination loss. The Spiro-OMeTAD filled GB is a good pathway to allow the holes to travel with less resistance to the device back contact. Therefore, the remarkable near 100% IQE of subject devices in accordance with one aspect of the subject development is most likely due or can be attributed to the combination effect of large single crystal grains and vertical BHJs.

In brief, as high PCE of 16.3±0.9% based on perovskite thin films containing large single-crystal grains and vertical GBs was thus obtained. Further, the hole transport medium Spiro-OMeTAD has been demonstrated to be infiltrated into the GBs to form vertical BHJs within a perovskite layer to suppress the recombination loss and enhance carrier collection in the vicinity of GBs, leading to IQEs approaching 100%. Thus, such an approach can present a facile and important alternative pathway to achieve the theoretical maximum PCE in hybrid perovskite solar cells.

In view of the above, it is to be appreciated that one aspect of the subject development involves a composition of matter such as composed of a vertical BHJ structure with large crystals and active grain boundaries. As described, such a composition can involve annealing and, if desired, infiltration of another material or media. Further, such a composition may rely on humidity processing such as follows:
a. Humidity processing such as herein described or provided can be utilized to drive crystallization of the perovskite and void-free film formation without annealing. This is or can be important such as for low-temperature processing on flexible plastic substrates. Without humidity, the films are in general not as well mixed and there may be or is little perovskite phase.
b. If the films are annealed, however, those films made without humidity processing tend to be more polycrystalline, although they may also form vertically-oriented single-crystalline with respect to the substrate. Further, they are typically of smaller grains that don't work as well in solar cell applications. In contrast, those films made with humidity processing are or tend to be consistently much larger single-crystalline grains, and vertically oriented. Thus, humidity processing such as herein described and provided is believed to be key toward ultimately forming large, vertically oriented, single crystalline perovskite grains.

Following annealing, structures such described or provided herein can be easily infiltrated such as, for example, herein shown to activate grain boundaries as active charge separation/collection channels in the solar cell in the BHJ geometry. Those skilled in the art and guided by the teachings herein provided will understand and appreciate that general BHJ structures such as herein described and provided are not necessarily limited to or require humidity processing.

The invention illustratively disclosed herein suitably may be practiced in the absence of any element, part, step, component, or ingredient which is not specifically disclosed herein.

While in the foregoing detailed description this invention has been described in relation to certain preferred embodiments thereof, and many details have been set forth for purposes of illustration, it will be apparent to those skilled in the art that the invention is susceptible to additional embodiments and that certain of the details described herein can be varied considerably without departing from the basic principles of the invention.

What is claimed is:

1. A method for making a hybrid perovskite film, said method comprising:
sequentially depositing respective layers of inorganic and organic hybrid perovskite precursors onto a substrate to form a hybrid perovskite film precursor and
exposing the hybrid perovskite film precursor to a humidified atmosphere to convert the inorganic and organic hybrid perovskite precursors to the hybrid perovskite.

2. The method of claim 1 wherein formation of the hybrid perovskite is free of thermal annealing processing and the hybrid perovskite is void-free.

3. The method of claim 1 additionally comprising the step of annealing the humidified atmosphere exposed hybrid perovskite film precursor.

4. The method of claim 1 wherein the humidified atmosphere corresponds to ambient air at room temperature with a humidity of at least 10%.

5. The method of claim 1 wherein the humidified atmosphere corresponds to ambient air at room temperature with a humidity of at least 20%.

6. The method of claim 1 wherein the humidified atmosphere corresponds to ambient air at room temperature with a humidity of at least 25%.

7. The method of claim 1 wherein the hybrid perovskite comprises a halide perovskite.

8. The method of claim 1 wherein the hybrid perovskite comprises an iodide perovskite.

9. The method of claim 1 wherein the hybrid perovskite comprises methylammonium lead iodide (CH₃NH₃PbI₃).

10. The method of claim 1 wherein the inorganic hybrid perovskite precursor comprises PbI₂.

11. The method of claim 10 wherein the PbI₂ layer is spin-coated using dimethylformamide (DMF).

12. The method of claim 1 wherein the organic hybrid perovskite precursor comprises CH₃NH₃I.

13. The method of claim 12 wherein the CH₃NH₃I layer is spin-coated using 2-propanol.

14. The method of claim 1 wherein the substrate comprises TiO₂/ITO glass.

15. A hybrid perovskite film formed by the method of claim 1.

16. A method for making the hybrid perovskite methylammonium lead iodide (CH₃NH₃PbI₃), said method comprising:
sequentially spin coating layers of an inorganic hybrid perovskite precursor comprising PbI₂ and layers of an organic hybrid perovskite precursor comprising CH₃NH₃I onto a substrate to form a hybrid perovskite film precursor and
exposing the hybrid perovskite film precursor to a humidified atmosphere corresponding to ambient air at room temperature with a humidity of at least 25% to convert the inorganic and organic hybrid perovskite precursors to form the hybrid perovskite.

17. The method of claim 16 wherein said method is free of thermal annealing processing and the hybrid perovskite is void-free.

18. A hybrid perovskite film formed by the method of claim 16.

19. The method of claim 16 additionally comprising:
annealing the humidified atmosphere-exposed hybrid perovskite film precursor to form a perovskite film with crystal grains forming vertically oriented grain boundaries.

20. A composition of matter comprising:
a hybrid perovskite film having crystalline columnar grains within a polycrystalline film, the hybrid perovskite film made by:
sequentially depositing respective layers of inorganic and organic hybrid perovskite precursors onto a substrate to form a hybrid perovskite film precursor and
exposing the hybrid perovskite film precursor to a humidified atmosphere to convert the inorganic and organic hybrid perovskite precursors to the hybrid perovskite.

21. The composition of matter of claim 20 where the hybrid perovskite film is void free.

22. The composition of matter of claim 20 wherein formation of the crystalline hybrid perovskite film with columnar grains additionally comprises:
annealing the humidified atmosphere-exposed hybrid perovskite film precursor to form the polycrystalline hybrid perovskite film having crystalline columnar grains.

23. The composition of matter of claim 20 having at least some of the grain boundaries between the columnar grains infiltrated with an infiltration media.

24. The composition of matter of claim 23 wherein the infiltration media is Spiro-OMeTAD or PCBM.
